(19) United States
(12) Patent Application Publication
(10) Pub. No.: US 2026/0215208 A1
(43) Pub. Date: Jul. 23, 2026

(54) SEMICONDUCTOR MANUFACTURING SYSTEM

(71) Applicant: SAMSUNG ELECTRONICS CO, LTD., Suwon-si (KR)

(72) Inventors: Kwangjae LEE, Suwon-si (KR); Ickhyun CHO, Osan-si (KR)

(73) Assignees: SAMSUNG ELECTRONICS CO, LTD., Suwon-si (KR); MIDAS TECHNOLOGY, Osan-si (KR)

(21) Appl. No.: 19/448,547

(22) Filed: Jan. 14, 2026

(30) Foreign Application Priority Data
Jan. 22, 2025 (KR) 10-2025-0009837

(51) Int. Cl. H10P 72/00; C23C 16/46; C23C 16/52

(52) U.S. Cl. CPC H10P 72/0431; C23C 16/463; C23C 16/52; H10P 72/0402; H10P 72/0604

(57) ABSTRACT

Provided is a semiconductor manufacturing system including a chiller configured to supply a coolant to semiconductor equipment, a flow sensor between the chiller and the semiconductor equipment, and a compensator configured to supply power to the flow sensor, wherein the compensator is further configured to receive a first sensor signal including flow rate information of the coolant from the flow sensor and transmit a second sensor signal to the semiconductor equipment based on the first sensor signal.

### CROSS-REFERENCE TO RELATED APPLICATION

This application claims priority to Korean Patent Application No. 10-2025-0009837, filed on January 22, 2025, in the Korean Intellectual Property Office, the disclosure of which is incorporated by reference herein in its entirety.

### BACKGROUND

Embodiments of the present disclosure relate to a semiconductor manufacturing system.

The semiconductor manufacturing system may include multiple types of semiconductor equipment that each perform a deposition process, an etching process, an exposure process, polishing process, and the like. A semiconductor device manufacturing process may be performed by selectively and repeatedly performing processes, such as photolithography, etching, diffusion, chemical vapor deposition, ion implantation, and metal deposition on a wafer. Due to the semiconductor device manufacturing process, a relatively high-temperature environment may be created in the semiconductor manufacturing system, and a method of controlling the temperature using a coolant is used to maintain the stable operation and process quality of the semiconductor manufacturing system.

In general, the power supply may be momentarily instable in industrial sites due to short-circuit in the power system, lightning strikes, and switching of large-capacity loads. A momentary power outage (e.g., less than 3 seconds) or a momentary voltage sag/dip when the voltage temporarily drops below the normal value can damage a programmable logic controller (PLC), a contactor, a relay, a starter, and a microcontroller that make up factory equipment, which can cause production equipment to stop operating, resulting in significant economic damage.

To prevent losses due to power supply abnormalities, a momentary power outage compensation device (or a momentary voltage drop compensation device) is used, and generally, an uninterruptible power supply (UPS) system and a voltage sag protector (VSP) are used.

### SUMMARY

One or more embodiments provide a semiconductor manufacturing system with improved stability and reliability.

In addition, the technical objective is not limited to the one mentioned above, and other technical objectives may be clearly understood by those skilled in the art from the description below.

According to an aspect of one or more embodiments, there is provided a semiconductor manufacturing system including a chiller configured to supply a coolant to semiconductor equipment, a flow sensor between the chiller and the semiconductor equipment, and a compensator configured to supply power to the flow sensor, wherein the compensator is further configured to receive a first sensor signal including flow rate information of the coolant from the flow sensor and transmit a second sensor signal to the semiconductor equipment based on the first sensor signal.

According to another aspect of one or more embodiments, there is provided a semiconductor manufacturing system including a chiller configured to supply a coolant to semiconductor equipment, a pipe between the chiller and the semiconductor equipment, the pipe being configured to supply the coolant, a flow sensor on the pipe, the flow sensor being configured to detect flow rate information of the coolant supplied to the semiconductor equipment and output a first sensor signal, and a compensator configured to receive the first sensor signal from the flow sensor and output a second sensor signal based on the first sensor signal, wherein the compensator includes a super capacitor.

According to still another aspect of one or more embodiments, there is provided a semiconductor manufacturing system including a flow sensor configured to detect flow rate information of a coolant supplied to semiconductor equipment, and output in real time a first sensor signal determined to be a normal signal or a defective signal, and a compensator including a supercapacitor and a timer configured to set an operation time, the compensator being configured to output a second sensor signal determined to be a normal signal or a defective signal, based on the first sensor signal received from the flow sensor and an operation of the timer, wherein the timer is configured to start operation at a time point when the first sensor signal transmitted to the compensator changes from a normal signal to a defective signal, and the second sensor signal output by the compensator during the operation time is the normal signal.

According to further still another aspect of one or more embodiments, there is provided an equipment stabilization method including charging a supercapacitor of a compensator, transmitting, by a flow sensor, a sensor signal to the compensator, transmitting, by the compensator, the sensor signal delayed during the operation time set by the operation of a timer to semiconductor equipment, and transmitting, by the compensator, a current sensor signal to the semiconductor equipment after the operation time set in the timer.

### BRIEF DESCRIPTION OF DRAWINGS

Embodiments will be more clearly understood from the following detailed description taken in conjunction with the accompanying drawings in which:

FIG. 1 is a schematic diagram of a portion of a semiconductor manufacturing system according to one or more embodiments;

FIGS. 2 and 3 are diagrams of semiconductor manufacturing systems, according to related examples;

FIG. 4 is a graph illustrating a flow rate and a sensor signal when a momentary voltage drop occurs;

FIG. 5 is a schematic diagram of the semiconductor manufacturing system according to one or more embodiments;

FIG. 6 is a schematic diagram of the semiconductor manufacturing system according to one or more embodiments;

FIG. 7 is a schematic flowchart of an equipment stabilization method using the semiconductor manufacturing system, according to one or more embodiments; and

FIG. 8 is a schematic flowchart of an equipment stabilization method using the semiconductor manufacturing system, according to one or more embodiments.

### DETAILED DESCRIPTION

Hereinafter, embodiments are described in detail with reference to the accompanying drawings. The same reference numerals are used for the same components in the drawings, and redundant description thereof is omitted.

In the following embodiments, the terms, such as first, second, and the like, are used for distinguishing one component from another rather than in a limiting sense. In the following embodiments, singular expressions include plural expressions unless the context clearly dictates otherwise.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

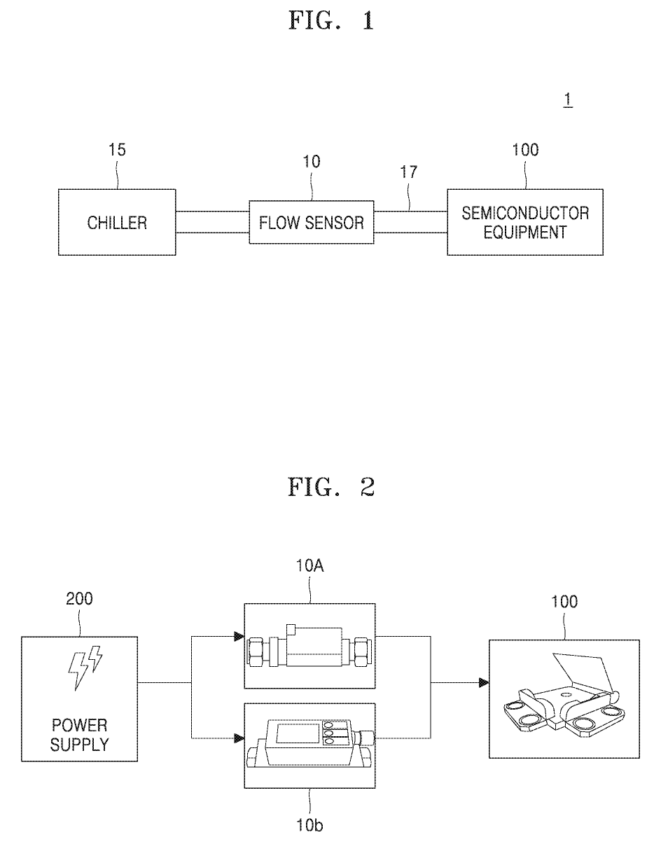

FIG. 1 is a schematic diagram of a portion of a semiconductor manufacturing system 1 according to one or more embodiments. Referring to FIG. 1, the semiconductor manufacturing system 1 may include a flow sensor 10, a chiller 15, a pipe 17, and semiconductor equipment 100.

In one or more embodiments, the semiconductor equipment 100 may include, for example, at least one of deposition process equipment, such as chemical vapor deposition (CVD) and physical vapor deposition (PVD), etching process equipment, ion implantation process equipment, polishing process equipment, such as chemical mechanical polishing (CMP), and exposure/photolithography process equipment.

The semiconductor equipment 100 may be exposed to a relatively high-temperature environment by heat generated in a semiconductor device manufacturing process and may be provided with a coolant for cooling along the pipe 17. The coolant may be supplied from the chiller 15 through the pipe 17. That is, the pipe 17 may provide a supply path for the coolant supplied to the semiconductor equipment 100. In one or more embodiments, a filter for removing foreign matter contained in the coolant may be arranged in the pipe 17.

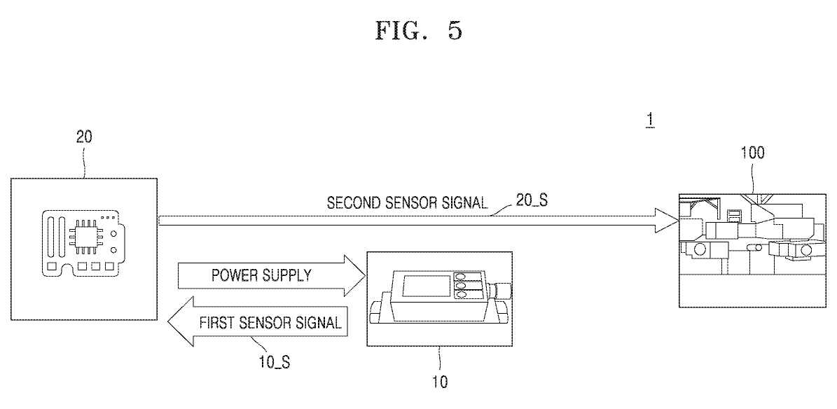

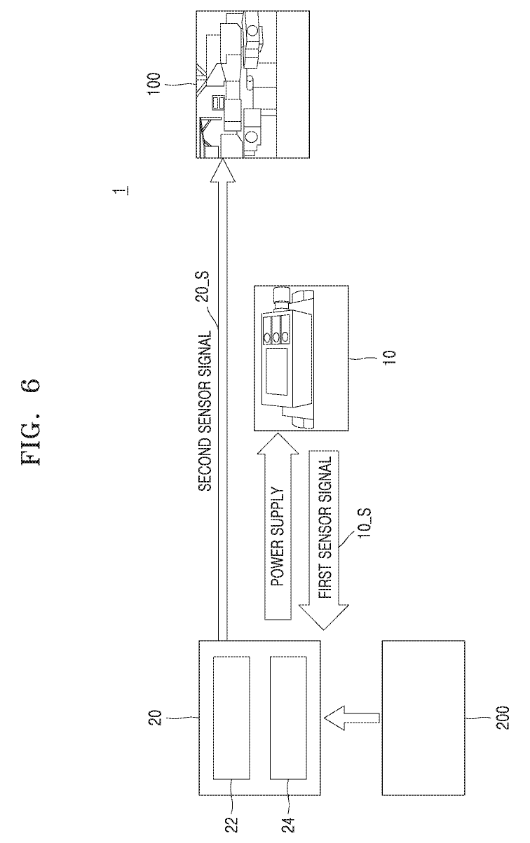

The flow sensor 10 may detect a flow rate of the coolant flowing through the pipe 17 to obtain flow rate information. The flow sensor 10 may output a sensor signal (hereinafter, a first sensor signal) determined based on the flow rate information. As described below with reference to FIGS. 5 and 6, in one or more embodiments, the flow sensor 10 may not directly transmit the first sensor signal to the semiconductor equipment 100 but may transmit the first sensor signal to a compensation module (compensator) 20 (see FIG. 5) and transmit a sensor signal (hereinafter, a second sensor signal) that is the same as or different from the first sensor signal to the semiconductor equipment 100, based on the transmitted first sensor signal. For example, the first sensor signal of the flow sensor 10 may be transmitted to the semiconductor equipment 100 through the compensation module 20. In one or more embodiments, the compensation module 20 may be connected between the flow sensor 10 and the semiconductor equipment 100.

In one or more embodiments, the flow sensor 10 may output the first sensor signal in real time. The flow sensor 10 may determine the first sensor signal based on the flow rate information of the measured coolant. The first sensor signal may be determined to be either a normal signal or a defective signal based on the flow rate information of the coolant measured by the flow sensor 10.

When the flow rate of the coolant flowing through the pipe 17 is outside of a certain reference flow rate range, the flow sensor 10 may output the defective signal as the first sensor signal. For example, the flow sensor 10 may output the defective signal when the flow rate of the coolant flowing through the pipe 17 is equal to or less than a reference value. When the flow rate of the coolant flowing through the pipe 17 is within the certain reference flow rate range, the flow sensor 10 may output the normal signal as the first sensor signal. For example, the flow sensor 10 may output the normal signal when the flow rate of the coolant flowing through the pipe 17 is greater than the reference value.

In one or more embodiments, the flow sensor 10 may include, for example, a capacitive sensor. The flow sensor 10 may output the first sensor signal by turning on/off a switch according to the flow rate of the coolant. In one or more embodiments, the flow sensor 10 may include a digital sensor. The flow sensor 10 may calculate (obtain) the flow rate of the coolant flowing along the pipe 17. The first sensor signal may include a negative-positive-negative (NPN) digital signal.

In one or more embodiments, the flow sensor 10 may further include a display capable of visually outputting the flow rate information, and an audio output unit that outputs an alarm when the detected flow rate decreases below a reference value.

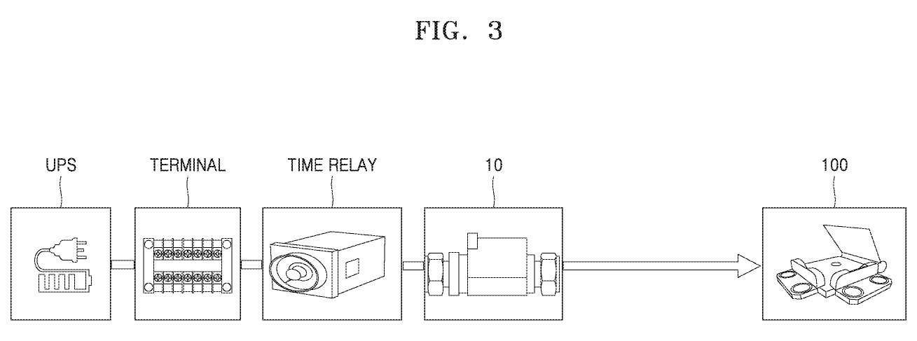

FIGS. 2 and 3 are diagrams of semiconductor manufacturing systems, according to related examples.

Referring to FIG. 2, a semiconductor manufacturing system according to a related example may include a power supply 200, flow sensors 10A and 10B, and semiconductor equipment 100. In the semiconductor manufacturing system according to the related example, the power supply 200 applies a voltage to the flow sensors 10A and 10B, and the flow sensors 10 A and 10B may detect the flow rate information of the coolant and transmit a sensor signal to the semiconductor equipment 100. In FIG. 2, the flow sensors 10A and 10B may include a capacitive flow sensor 10A or a digital flow sensor 10B.

When the power supply is instable, e.g., a momentary voltage drop, in the semiconductor manufacturing system of FIG. 2, an uninterruptible power supply (UPS) as shown in FIG. 3 may be used to compensate for the voltage supplied to the flow sensors 10A and 10B. When the momentary voltage drop occurs in the semiconductor manufacturing system according to the related example, the flow sensor 10 may be supplied with a voltage from the UPS. The flow sensor 10 of FIG. 3 may correspond to at least one of the flow sensors 10A and 10B of FIG. 2.

Referring to FIG. 3, a semiconductor manufacturing system according to a related example may include a UPS, a terminal, and a time relay. The UPS may temporarily provide the power using batteries or the like to maintain a stable power supply in the event of a momentary power outage or a momentary voltage drop. The UPS may further include a battery and an inverter to convert DC to AC, and a controller to control the operation of the UPS. The terminal may function as a connector for electrically connecting the UPS to the time relay or electrically connecting the UPS to the flow sensors 10A and 10B. The time relay may set a specific time delay to delay a signal or maintain operations for a specific time period.

The semiconductor manufacturing systems, according to the related examples of FIGS. 2 and 3, may compensate for the voltage supplied to the flow sensor 10 when the momentary voltage drop occurs through the UPS. However, the sensor signal of the flow sensor 10 may be directly transmitted to the semiconductor equipment 100, thereby degrading the stability of the semiconductor manufacturing systems due to an equipment alarm. In other words, the flow rate of the coolant may change due to a momentary abnormal operation of the chiller 15 caused by the momentary voltage drop, and the flow sensor 10 may sensitively react to such a temporary change in the flow rate to transmit the defective signal to the semiconductor equipment 100, thereby causing and/or providing the equipment alarm.

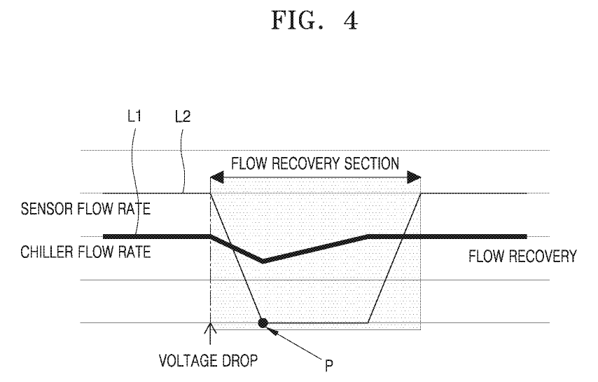

FIG. 4 is a graph illustrating the flow rate and the sensor signal when the momentary voltage drop occurs. In FIG. 4, the horizontal axis represents the time flow and the vertical axis represents the flow rate.

Referring to FIG. 4, although the chiller flow rate L1 of the coolant recovers and increases back to its normal state in a relatively short time after a slight decrease in the chiller flow rate L1 occurs when the momentary voltage drop occurs, the sensor flow rate L2 measured by the flow sensor 10 may reach a point P as a reference for outputting the defective signal, thereby causing and/providing the equipment alarm.

The semiconductor manufacturing system, according to one or more embodiments, may supply the power to the flow sensor 10 through the compensation module 20 (see FIG. 5), while transmitting the sensor signal (the second sensor signal) to the semiconductor equipment 100 based on the sensor signal (the first sensor signal) transmitted from the flow sensor 10, thereby preventing the equipment alarm from occurring due to a temporary change in the flow rate caused by the momentary voltage drop.

FIGS. 5 and 6 are schematic diagrams of the semiconductor manufacturing system according to one or more embodiments. The semiconductor manufacturing system 1 according to one or more embodiments may include the flow sensor 10, the compensation module 20, and the semiconductor equipment 100.

As used herein, the term “module” may refer to a functional and structural combination of hardware for performing operations of one or more embodiments and software for running the hardware. For example, the “module” may refer to a logical unit of certain codes and a hardware resource for performing the certain codes and may not necessarily refer to physically-connected codes or a type of hardware.

The flow sensor 10 may detect the flow rate of the coolant flowing through the pipe 17 (FIG. 1) to obtain the flow rate information. The flow sensor 10 may output a first sensor signal 10_S determined based on the obtained flow rate information. Although the flow sensor 10 of FIG. 5 is illustrated in the same manner as the flow sensor 10B of FIG. 2, the flow sensor 10 according to one or more embodiments may include the capacitive sensor and/or the digital sensor. The flow sensor 10, according to one or more embodiments, may correspond to the flow sensor 10 described with reference to FIG. 1 and/or the flow sensors 10A and 10B described with reference to FIG. 2. The flow sensor 10 may transmit the first sensor signal 10_S to the compensation module 20.

The compensation module 20 may supply the power to the flow sensor 10 and receive the first sensor signal 10_S from the flow sensor 10. The compensation module 20 may transmit a second sensor signal 20_S to the semiconductor equipment 100 based on the first sensor signal 10_S. The compensation module 20 may receive the first sensor signal 10_S from the flow sensor 10 in real time and may transmit the second sensor signal 20_S to the semiconductor equipment 100 in real time.

In one or more embodiments, the first sensor signal 10_S output by the flow sensor 10 may be either the normal signal or the defective signal. When the flow rate of the coolant sensed by the flow sensor 10 is within the certain reference flow rate range, the flow sensor 10 may output the normal signal as the first sensor signal 10_S. When the flow rate of the coolant sensed by the flow sensor 10 is outside of the certain reference flow rate range, the flow sensor 10 may output the defective signal as the first sensor signal 10_S. The normal signal or the defective signal output from the flow sensor 10 may be transmitted to the compensation module 20.

The compensation module 20 may output the second sensor signal 20_S based on the first sensor signal 10_S. The second sensor signal 20_S may be the same as or different from the first sensor signal 10_S. The second sensor signal 20_S output by the compensation module 20 may be either the normal signal or the defective signal. In one or more embodiments, although the flow sensor 10 transmits the defective signal as the first sensor signal 10_S to the compensation module 20, the compensation module 20 may transmit the normal signal as the second sensor signal 20_S to the semiconductor equipment 100 under a certain condition.

Referring to FIG. 6, the compensation module 20 may include a capacitor 22. The capacitor 22 having a very high capacity may include a super capacitor capable of being repeatedly charged and discharged. The capacitor 22 included in the compensation module 20 may supply the power to the flow sensor 10 during the momentary voltage drop to stabilize the power supply. The compensation module 20 may be connected to the power supply 200, and the capacitor 22 may be charged through the power supply 200.

The compensation module 20 may further include a timer 24. In one or more embodiments, the timer 24 may include a time relay device. The timer 24 may be configured to cause the compensation module 20 to communicate the delayed sensor signal to the semiconductor equipment 100. For example, the timer 24 may be configured to delay the first sensor signal 10_S received by the compensation module 20, so as to transmit the second sensor signal 20_S different from the first sensor signal 10_S received in real time to the semiconductor equipment 100.

The timer 24 may start operations based on the first sensor signal 10_S. The timer 24 may start the operations when the flow sensor 10 transmits the defective signal as the first sensor signal 10_S to the compensation module 20. The timer 24 may start the operations at a time point when the first sensor signal 10_S of the flow sensor 10 is changed from the normal signal to the defective signal.

The timer 24 may delay the first sensor signal 10_S for a set time period (or an operation time period). The compensation module 20 may output the second sensor signal 20_S as the normal signal rather than the defective signal during a time period set in the timer 24 from the time point when the first sensor signal 10_S is changed from the normal signal to the defective signal. After the time period set in the timer 24 ends, the compensation module 20 may output, as the second sensor signal 20_S, a signal that is the same as the first sensor signal 10_S input in real time. For example, the second sensor signal 20_S may be the same as the first sensor signal 10_S during a time period before the operation of the timer 24 starts and after the operation of the timer 24 ends. In one or more embodiments, the timer 24 may be set in a range of about 0 second to about 15 seconds.

For example, when the timer 24 is set to 10 seconds, the compensation module 20 may output the second sensor signal 20_S as the normal signal rather than the defective signal for 10 seconds from the time point when the first sensor signal 10_S is changed from the normal signal to the defective signal.

After 10 seconds have elapsed since the operation of the timer 24, the compensation module 20 may output the second sensor signal 20_S that is the same as the first sensor signal 10_S input in real time. When the first sensor signal 10_S is still the defective signal after 10 seconds, the compensation module 20 may transmit the defective signal as the second sensor signal 20_S to the semiconductor equipment 100, thereby causing and/or providing the equipment alarm. When the first sensor signal 10_S is the normal signal after 10 seconds, the compensation module 20 may transmit the normal signal as the second sensor signal 20_S to the semiconductor equipment 100.

Therefore, the defective signal of the flow sensor 10 generated within the time period set in the timer 24 may not be transmitted to the semiconductor equipment 100. That is, although the flow rate is temporarily changed due to the momentary power outage or the momentary voltage drop, the semiconductor equipment 100 may receive the normal signal (the second sensor signal) for the time period set in the timer 24, thereby improving the stability and reliability of the semiconductor manufacturing system 1.

In one or more embodiments, the compensation module 20 may reduce the weight of the semiconductor manufacturing system 1 by configuring the capacitor 22 and the timer 24 on a single board.

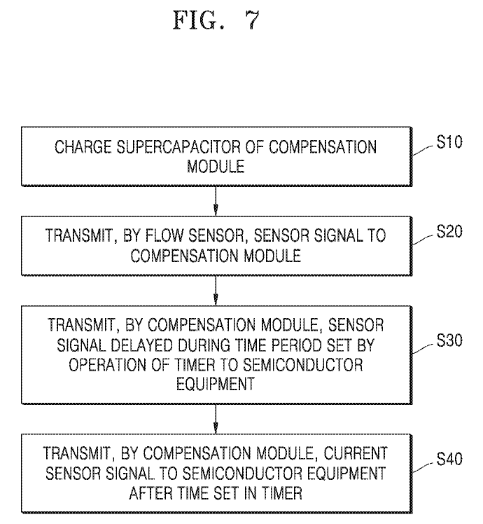

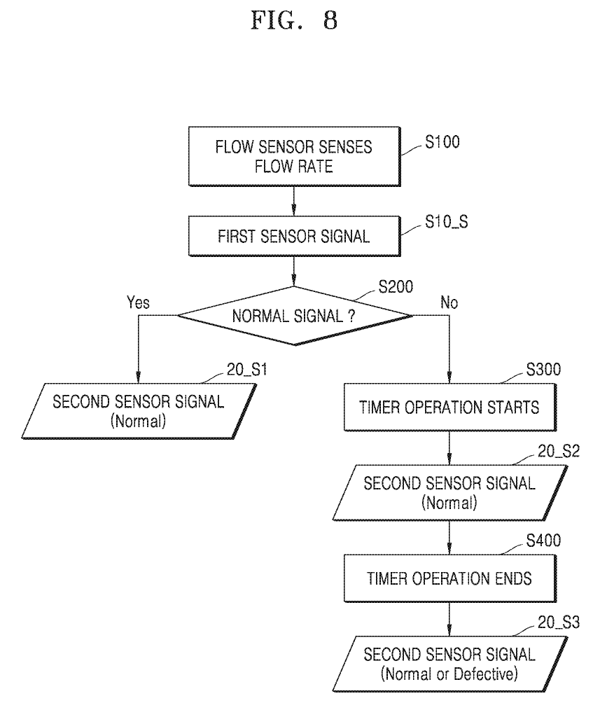

FIGS. 7 and 8 are schematic flowcharts of an equipment stabilization method using the semiconductor manufacturing system, according to one or more embodiments.

Referring to FIG. 7 together with FIG. 6, the equipment stabilization method according to one or more embodiments may include operation S10 of charging the capacitor 22 of the compensation module 20, operation S20 of transmitting, by the flow sensor 10, the sensor signal (the first sensor signal 10_S) to the compensation module 20, operation S30 of transmitting, by the compensation module 20, the delayed sensor signal (the second sensor signal 20_S) for a time period set in the timer 24 to the semiconductor equipment 100, and operation S40 of transmitting, after the time period set in the timer 24, the current sensor signal (the first sensor signal 10_S) to the semiconductor equipment 100.

The capacitor 22 of the compensation module 20 may include a super capacitor, and operation S10 of charging the capacitor 22 may include charging the capacitor 22 from the power supply 200 connected with the compensation module 20.

Operation S20 of transmitting, by the flow sensor 10, the sensor signal to the compensation module 20 may include detecting, by the flow sensor 10, the flow rate of the coolant flowing into the semiconductor equipment 100 to obtain the flow rate information, and transmitting the first sensor signal 10_S, which is determined to be either the normal signal or the defective signal based on the flow rate information, to the compensation module 20.

Operation S30 of transmitting, by the compensation module 20, the delayed sensor signal to the semiconductor equipment 100 based on the operation of the timer 24, may include starting to operate, by the timer 24, when the first sensor signal 10_S input to the compensation module 20 is the defective signal, and transmitting, by the compensation module 20, the delayed sensor signal (the normal signal as the second sensor signal 20_S) to the semiconductor equipment 100.

Operation S40 of transmitting, by the compensation module 20, the current sensor signal to the semiconductor equipment 100 after the time period set in the timer 24 may include outputting, as the second sensor signal 20_S, a signal that is the same as the first sensor signal 10_S input to the compensation module 20 in real time after the timer 24 ends.

Referring to FIG. 8 together with FIG. 6, in the equipment stabilization method using the semiconductor manufacturing system 1 according to one or more embodiments, in operation S100, the flow sensor 10 may sense the flow rate of the coolant to output the first sensor signal 10_S. The first sensor signal 10_S may be transmitted to the compensation module 20.

In operation S200, when the first sensor signal 10_S is the normal signal (S200, YES), the compensation module 20 may output, as the second sensor signal 20_S1, the normal signal that is the same as the first sensor signal 10_S. The second sensor signal 20_S may be transmitted to the semiconductor equipment 100.

In operation S200, when the first sensor signal 10_S is not the normal signal (S200, NO) (that is, the first sensor signal 10_S is the defective signal), the timer 24 of the compensation module 20 may start to operate in operation S300. By the operation of the timer 24, the compensation module 20 may output the normal signal as the second sensor signal 20_S1 even though the first sensor signal 10_S is the defective signal during the time period set in the timer 24. The second sensor signal 20_S may be transmitted to the semiconductor equipment 100.

Thereafter, in operation S400, the operation of the timer 24 may end. After the operation of the timer 24 ends, the compensation module 20 may output the second sensor signal 20_S3 that is same as the first sensor signal 10_S. For example, when the first sensor signal 10_S input to the compensation module 20 in real time is the normal signal, the compensation module 20 may output the normal signal as the second sensor signal 20_S3, and when the first sensor signal 10_S input in real time to the compensation module 20 is the defective signal, the compensation module 20 may output the defective signal as the second sensor signal 20_S3. The second sensor signal 20_S3 may be transmitted to the semiconductor equipment 100.

For example, in the equipment stabilization method using the semiconductor manufacturing system 1 according to one or more embodiments may prevent the defective signal from being transmitted to the semiconductor equipment 100 during a relatively short (temporary) change in the flow rate within the time period set in the timer 24, thereby enabling the semiconductor equipment 100 to be operated stably even when the momentary power outage or the momentary voltage drop occurs.

At least a part of each operation included in the equipment stabilization method using the semiconductor manufacturing system 1 according to one or more embodiments may be performed by an electronic device including memory and one or more processors.

The memory may store computer-readable instructions. When the instructions stored in the memory are executed by the processor, the processor may process operations defined by the instructions. The memory may include, for example, random-access memory (RAM), dynamic random-access memory (DRAM), static random-access memory (SRAM), or other forms of non-volatile memory.

The one or more processors according to one or more embodiments may control the overall operation of the electronic device. The processor may be a hardware-implemented device having circuitry with a physical structure for executing desired operations. The desired operations may include code or instructions contained in a program. The hardware-implemented device may include a microprocessor, a central processing unit (CPU), a graphics processing unit (GPU), a processor core, a multi-core processor, a multi-processor, an application-specific integrated circuit (ASIC), a field programmable gate array (FPGA), a neural processing unit (NPU), and the like.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor manufacturing system comprising:
a chiller configured to supply a coolant to semiconductor equipment;
a flow sensor between the chiller and the semiconductor equipment; and
a compensator configured to supply power to the flow sensor,
wherein the compensator is further configured to receive a first sensor signal comprising flow rate information of the coolant from the flow sensor and transmit a second sensor signal to the semiconductor equipment based on the first sensor signal.

2. The semiconductor manufacturing system of claim 1, wherein the compensator comprises a capacitor.

3. The semiconductor manufacturing system of claim 2, wherein the compensator is between the flow sensor and the semiconductor equipment.

4. The semiconductor manufacturing system of claim 1, wherein the compensator comprises a timer configured to operate based on the first sensor signal.

5. The semiconductor manufacturing system of claim 4, wherein the first sensor signal comprises a normal signal and a defective signal, and
wherein the timer is further configured to start operation based on the compensator receiving the defective signal as the first sensor signal from the flow sensor.

6. The semiconductor manufacturing system of claim 5, wherein the second sensor signal comprises a normal signal and a defective signal, and
wherein the compensator is further configured to transmit the normal signal as the second sensor signal to the semiconductor equipment for a time period set in the timer.

7. The semiconductor manufacturing system of claim 6, wherein the second sensor signal is the same as the first sensor signal before the operation of the timer starts and after the operation of the timer ends.

8. The semiconductor manufacturing system of claim 1, wherein the flow sensor comprises a capacitive sensor or a digital sensor.

9. The semiconductor manufacturing system of claim 8, wherein the second sensor signal comprises a negative-positive-negative (NPN) digital signal.

10. The semiconductor manufacturing system of claim 1, wherein the semiconductor equipment is configured to perform a chemical vapor deposition (CVD) process.

11. A semiconductor manufacturing system comprising:
a chiller configured to supply a coolant to semiconductor equipment;
a pipe between the chiller and the semiconductor equipment, the pipe being configured to supply the coolant;
a flow sensor on the pipe, the flow sensor being configured to detect flow rate information of the coolant supplied to the semiconductor equipment and output a first sensor signal; and
a compensator configured to receive the first sensor signal from the flow sensor and output a second sensor signal based on the first sensor signal,
wherein the compensator comprises a super capacitor.

12. The semiconductor manufacturing system of claim 11, wherein, based on a normal signal being input to the compensator as the first sensor signal, the compensator is further configured to output the second sensor signal, which is the same as the first sensor signal, to the semiconductor equipment.

13. The semiconductor manufacturing system of claim 11, wherein the flow sensor is further configured to output a defective signal as the first sensor signal to the compensator based on the sensed flow rate of the coolant being outside of a certain reference flow rate range.

14. The semiconductor manufacturing system of claim 13, wherein the compensator comprises a timer, and
wherein the timer is configured to start operation based on the defective signal being input to the compensator as the first sensor signal.

15. The semiconductor manufacturing system of claim 14, wherein, based on the defective signal being input to the compensator as the first sensor signal, the compensator is further configured to output the second sensor signal, which is different from the first sensor signal, to the semiconductor equipment during a time period set in the timer.

16. The semiconductor manufacturing system of claim 15, wherein, during the time period set in the timer, the second sensor signal is the same as the first sensor signal input to the compensator immediately before the operation of the timer.

17. The semiconductor manufacturing system of claim 11, wherein an alarm of the semiconductor equipment is generated based on the compensator outputting the defective signal as the second sensor signal to the semiconductor equipment.

18. The semiconductor manufacturing system of claim 11, wherein the flow sensor comprises a digital sensor configured to obtain and indicate a flow rate of the coolant along the pipe.

19. A semiconductor manufacturing system comprising:
a flow sensor configured to detect flow rate information of a coolant supplied to semiconductor equipment, and output in real time a first sensor signal determined to be a normal signal or a defective signal; and
a compensator comprising a supercapacitor and a timer configured to set an operation time, the compensator being configured to output a second sensor signal determined to be a normal signal or a defective signal, based on the first sensor signal received from the flow sensor and an operation of the timer,
wherein the timer is configured to start operation at a time point when the first sensor signal transmitted to the compensator changes from a normal signal to a defective signal, and the second sensor signal output by the compensator during the operation time is the normal signal.

20. The semiconductor manufacturing system of claim 19, wherein, based on the first sensor signal transmitted to the compensator at a time point when the operation of the timer ends being the defective signal, the second sensor signal output by the compensator is the defective signal.
